(19) United States
(12) Patent Application Publication
(10) Pub. No.: US 2024/0155836 A1
(43) Pub. Date: May 9, 2024

(54) SEMICONDUCTOR DEVICE AND METHOD OF MANUFACTURING SAME

(71) Applicant: Samsung Electronics Co., Ltd., Suwon-si (KR)

(72) Inventors: Joonyoung Kang, Suwon-si (KR); Hoju Song, Suwon-si (KR); Kanguk Kim, Suwon-si (KR); Seokhyun Kim, Suwon-si (KR); Youngjun Kim, Suwon-si (KR); Jooncheol Kim, Suwon-si (KR); Jinwoong Kim, Suwon-si (KR); Hoin Ryu, Suwon-si (KR); Hyeran Lee, Suwon-si (KR)

(21) Appl. No.: 18/492,821

(22) Filed: Oct. 24, 2023

(30) Foreign Application Priority Data
Nov. 3, 2022 (KR) 10-2022-0145560

(51) Int. Cl. H10B 12/00

(52) U.S. Cl. CPC H10B 12/485; H10B 12/02; H10B 12/315; H10B 12/34; H10B 12/482

(57) ABSTRACT

Semiconductor devices may include: a substrate including a plurality of active areas defined by a device isolation layer; a plurality of bit lines extending on the substrate in a first horizontal direction; a plurality of insulation fences that are spaced apart from each other in the first horizontal direction in a space between two adjacent bit lines among the plurality of bit lines on the substrate; a plurality of buried contacts that are between the adjacent two bit lines among the plurality of bit lines and are arranged alternately with the plurality of insulation fences along the first horizontal direction on the substrate, the plurality of buried contacts being connected to the plurality of active areas, respectively; and a plurality of insulating layer, each of which is between a respective one of the plurality of insulation fences and a respective one of the plurality of buried contacts.

### CROSS-REFERENCE TO RELATED APPLICATION

This application is based on and claims priority under 35 U.S.C. § 119 to Korean Patent Application No. 10-2022-0145560, filed on Nov. 3, 2022, in the Korean Intellectual Property Office, the disclosure of which is incorporated by reference herein in its entirety.

### BACKGROUND

The inventive concept relates to a semiconductor device and a method of manufacturing the same, and more particularly, to a semiconductor device including bit lines, and a manufacturing method of the semiconductor device.

For the downscaling of integrated circuit devices, the size of individual fine circuit patterns is further decreasing. Also, due to the high integration of integrated circuit devices, a width of bit lines is decreasing, and the difficulty of processes for forming contacts between the bit lines is increasing.

### SUMMARY

The inventive concept provides a semiconductor device, for which the difficulty of the process of forming contacts between bit lines may be reduced.

The inventive concept also provides a manufacturing method of a semiconductor device, for which the difficulty of the process of forming contacts between bit lines may be reduced.

According to some embodiments of the inventive concept, there is provided a semiconductor device including a substrate including a plurality of active areas defined by a device isolation layer, a plurality of bit lines extending on the substrate in a first horizontal direction, a plurality of insulation fences that are spaced apart from each other in the first horizontal direction in a space between two adjacent bit lines among the plurality of bit lines on the substrate, a plurality of buried contacts that are between the two adjacent bit lines among the plurality of bit lines and are arranged alternately with the plurality of insulation fences along the first horizontal direction on the substrate, the plurality of buried contacts being connected to the plurality of active areas, respectively, and a plurality of insulating layers, each of which is between a respective one of the plurality of insulation fences and a respective one of the plurality of buried contacts.

According to some embodiments of the inventive concept, there is provided a semiconductor device including a substrate including a plurality of active areas defined by a device isolation layer, a plurality of bit lines extending on the substrate in a first horizontal direction, a plurality of spacers on respective sidewalls of the plurality of bit lines, a plurality of insulation fences that are spaced apart from each other in the first horizontal direction in a space between two bit lines among the plurality of bit lines on the substrate, each of the plurality of bit lines contacting a respective pair of the plurality of spacers, a plurality of buried contacts that are between the two bit lines among the plurality of bit lines and are arranged alternately with the plurality of insulation fences along the first horizontal direction, on the substrate, the plurality of buried contacts being connected to the plurality of active areas, respectively, a plurality of insulating layers between a respective one of the plurality of insulation fences and a respective one of the plurality of buried contacts, and a string insulating layer on a lower sidewall of at least one insulation fence among the plurality of insulation fences and under one of the plurality of spacers.

According to some embodiments of the inventive concept, there is provided a semiconductor device including a substrate including a plurality of active areas defined by a device isolation layer, a plurality of bit lines extending on the substrate in a first horizontal direction, a plurality of spacers on respective sidewalls of the plurality of bit lines, a word line in a lower portion of a word line trench extending in a second horizontal direction crossing the first horizontal direction, in the substrate, a word line capping layer in an upper portion of the word line trench and covering an upper surface of the word line, a plurality of insulation fences that are spaced apart from each other in the first horizontal direction in a space between two bit lines among the plurality of bit lines on the substrate, each of the plurality of bit lines contacting a respective pair of the plurality of spacers, a plurality of buried contacts that are between the two bit lines among the plurality of bit lines and are arranged alternately with the plurality of insulation fences along the first horizontal direction, on the substrate, the plurality of buried contacts being connected to the plurality of active areas, respectively, a plurality of insulating layers, each of which is between a respective one of the plurality of insulation fences and a respective one of the plurality of buried contacts, a string insulating layer that is on a lower sidewall of at least one insulation fence among the plurality of insulation fences and is under one of the plurality of spacers, and a plurality of landing pads respectively on the plurality of buried contacts.

According to some embodiments of the inventive concept, there is provided a method of manufacturing a semiconductor device, the method including defining a plurality of active areas by forming a device isolation layer on a substrate, forming, on the substrate, a plurality of bit lines extending in a first horizontal direction and a plurality of spacers on respective sidewalls of the plurality of bit lines, forming a plurality of buried contacts that are connected to the plurality of active areas, respectively, are in a space between two adjacent bit lines of the plurality of bit lines, and are spaced apart from each other in the first horizontal direction, forming a plurality of insulating layers by performing an oxidation process on sidewalls of the plurality of buried contacts, and forming a plurality of insulation fences that are between the two adjacent bit lines of the plurality of bit lines and are arranged alternately with the plurality of buried contacts along the first horizontal direction.

According to some embodiments of the inventive concept, there is provided a method of manufacturing a semiconductor device, the method including defining a plurality of active areas by forming a device isolation layer on a substrate, forming, on the substrate, a plurality of bit lines extending in a first horizontal direction, and a plurality of spacers on respective sidewalls of the plurality of bit lines, forming a preliminary contact layer to fill a space between two adjacent bit lines of the plurality of bit lines, on the substrate, removing first portions of the preliminary contact layer such that a plurality of buried contacts are formed in the space between the plurality of bit lines, forming a plurality of insulating layer by performing an oxidation process on sidewalls of the plurality of buried contacts, in the space between the plurality of bit lines, and forming a plurality of insulation fences that are between the two adjacent bit lines and are arranged alternately with the plurality of buried contacts, in the space between the plurality of bit lines, wherein in the removing of the first portions of the preliminary contact layer, a residue of the preliminary contact layer remains on the sidewall of one of the plurality of spacers, and in the forming of the plurality of insulating layers, a string insulating layer is formed from the residue by the oxidation process.

According to some embodiments of the inventive concept, there is provided a method of manufacturing a semiconductor device, the method including defining a plurality of active areas by forming a device isolation layer on a substrate, forming a word line trench extending in a second horizontal direction, by removing a portion of the substrate, sequentially forming a word line and a word line capping layer in the word line trench, forming, on the substrate, a plurality of bit lines extending in a first horizontal direction crossing the second horizontal direction, and a plurality of spacers on respective sidewalls of the plurality of bit lines, forming a preliminary contact layer to fill a space between two adjacent bit lines of the plurality of bit lines, on the substrate, removing first portions of the preliminary contact layer such that a plurality of buried contacts are formed in the space between the two adjacent bit lines of the plurality of bit lines, forming a plurality of insulating layers by performing a selective oxidation process on sidewalls of the plurality of buried contacts, in the space between the two adjacent bit lines of the plurality of bit lines, and forming a plurality of insulation fences that are between the two adjacent bit lines of the plurality of bit lines and are arranged alternately with the plurality of buried contacts along the first horizontal direction.

### BRIEF DESCRIPTION OF THE DRAWINGS

Some example embodiments will be more clearly understood from the following detailed description taken in conjunction with the accompanying drawings in which:

FIG. 1 is a layout diagram of a semiconductor device according to some embodiments;

FIG. 2 is an enlarged layout diagram of region II of FIG. 1 according to some embodiments;

FIG. 3 is a cross-sectional view taken along line A-A′ of FIG. 2 according to some embodiments;

FIG. 4 is a cross-sectional view taken along line B-B′ of FIG. 2 according to some embodiments;

FIG. 5 is a cross-sectional view taken along line C-C′ of FIG. 2 according to some embodiments;

FIG. 6 is an enlarged view of region CX1 of FIG. 4 according to some embodiments;

FIG. 7 is an enlarged view of region CX2 of FIG. 5 according to some embodiments;

FIG. 8 is a plan view at a first vertical level of FIG. 4 according to some embodiments;

FIG. 9 is a plan view at a second vertical level of FIG. 4 according to some embodiments;

FIGS. 10 and 11 are each a cross-sectional view of a semiconductor device according to some embodiments;

FIG. 12 is a cross-sectional view of a semiconductor device according to some embodiments; and

FIGS. 13A, 13B, 13C, 14A, 14B, 14C, 15A, 15B, 15C, 16A, 16B, 16C, 17A, 17B, 17C, 18A, 18B, 18C, 19A, 19B, 19C, 20A, 20B and 20C are cross-sectional views illustrating a method of manufacturing a semiconductor device according to some embodiments.

### DETAILED DESCRIPTION OF THE EMBODIMENTS

Hereinafter, some example embodiments of the inventive concept will be described in detail with reference to the attached drawings.

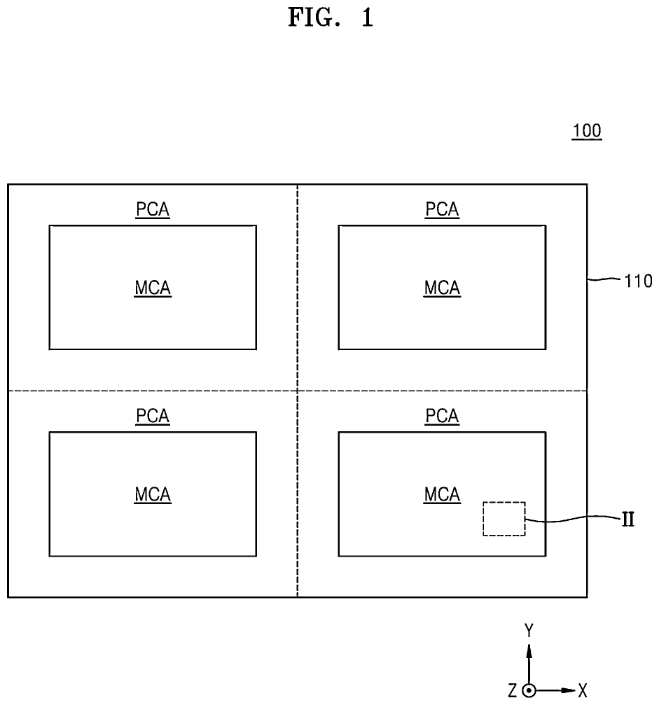

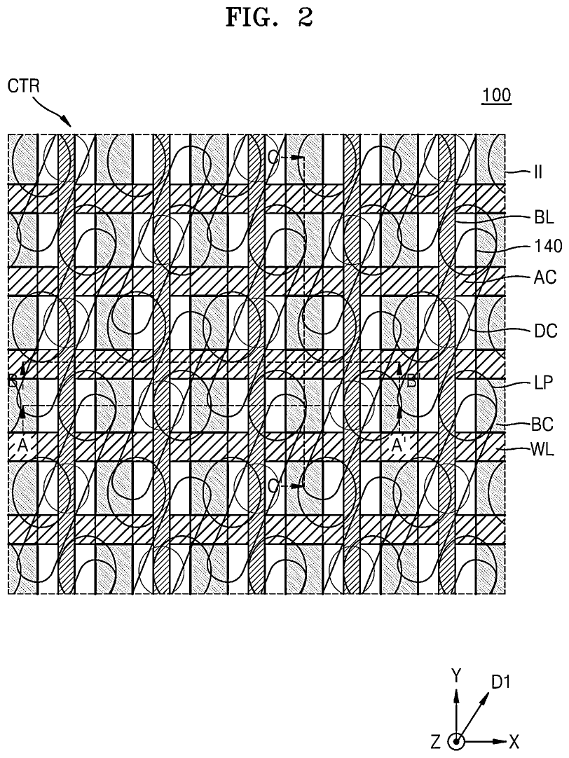

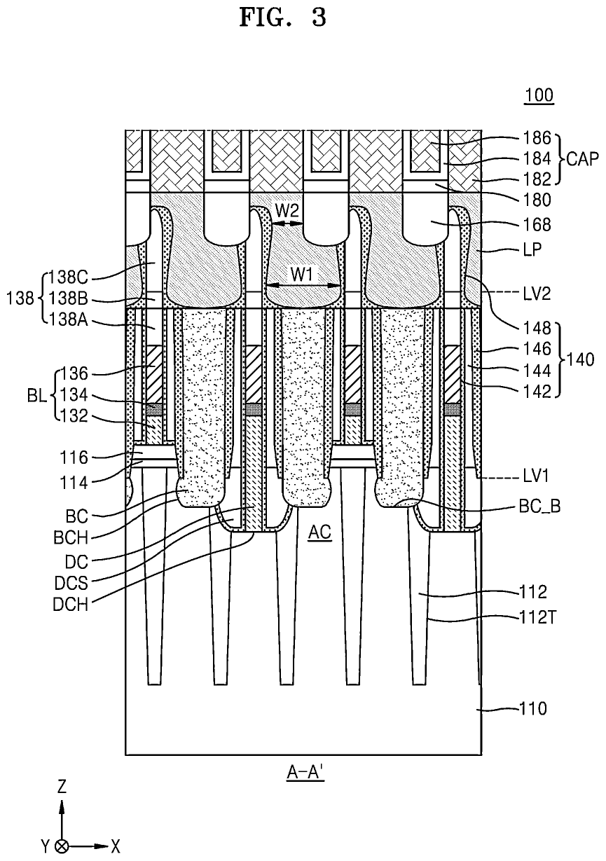

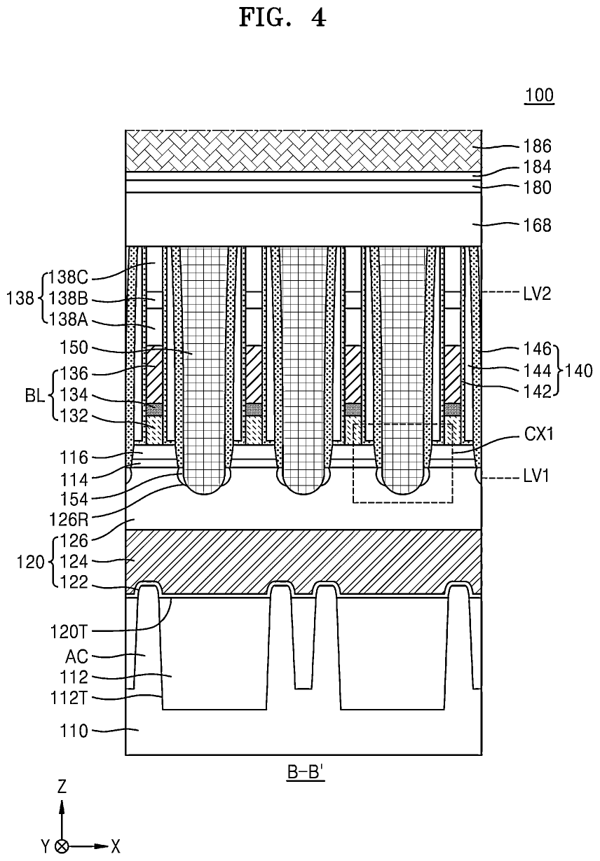

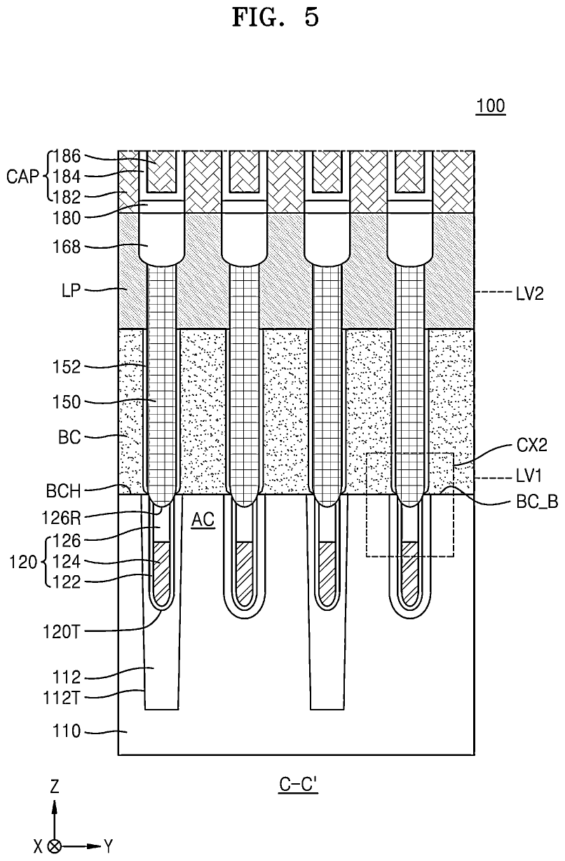

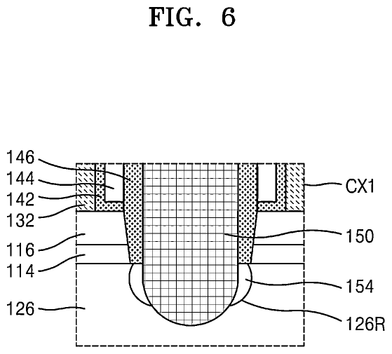

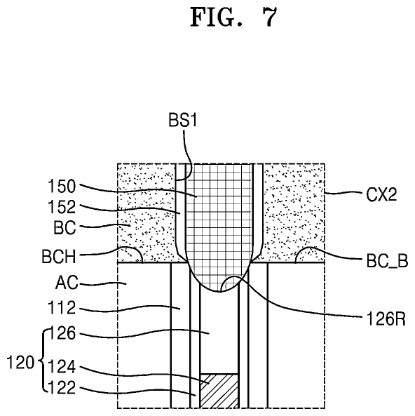

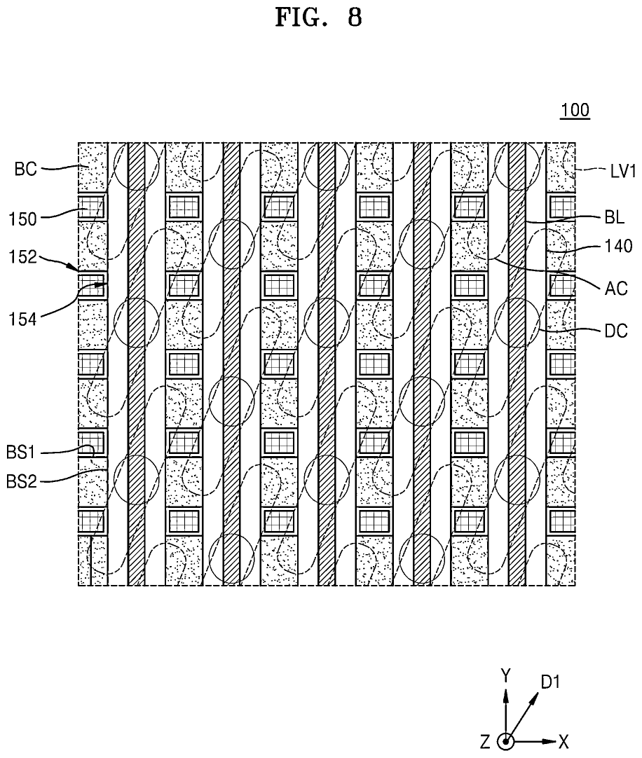

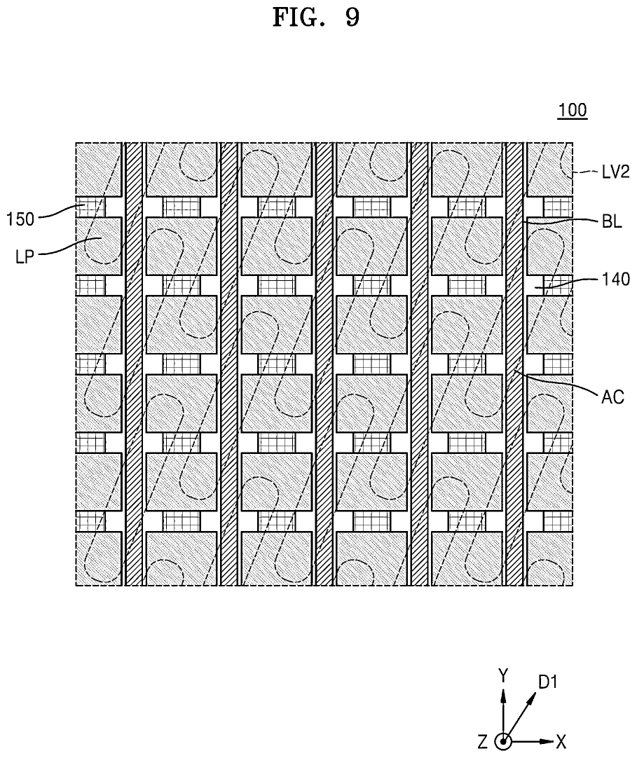

FIG. 1 is a layout diagram of a semiconductor device according to some embodiments of the inventive concept. FIG. 2 is an enlarged layout diagram of region II of FIG. 1. FIG. 3 is a cross-sectional view taken along line A-A′ of FIG. 2. FIG. 4 is a cross-sectional view taken along line B-B′ of FIG. 2. FIG. 5 is a cross-sectional view taken along line C-C′ of FIG. 2. FIG. 6 is an enlarged view of region CX1 of FIG. 4. FIG. 7 is an enlarged view of region CX2 of FIG. 5. FIG. 8 is a plan view at a first vertical level LV1 of FIG. 4. FIG. 9 is a plan view at a second vertical level LV2 of FIG. 4.

Referring to FIGS. 1 to 9, a semiconductor device 100 may include a substrate 110 including a cell array area MCA and a peripheral circuit area PCA. The cell array area MCA may include a memory cell area of a dynamic random access memory (DRAM) device, and the peripheral circuit area PCA may include a core area of the DRAM device or a peripheral circuit area. For example, the cell array area MCA may include a cell transistor CTR and a capacitor structure CAP connected thereto, and the peripheral circuit area PCA may include a peripheral circuit transistor (not shown) for transferring a signal and/or power to the cell transistor CTR included in the cell array area MCA. In some embodiments, the peripheral circuit transistor may configure various circuits such as a command decoder, control logic, an address buffer, a row decoder, a column decoder, a sense amplifier, and a data input/output circuit.

A device isolation trench 112T may be formed in the substrate 110, and a device isolation layer 112 may be formed in the device isolation trench 112T. A plurality of active areas AC may be defined on the substrate 110 by the device isolation layer 112.

As illustrated in FIG. 2, each of the plurality of active areas AC may be arranged to have a major axis in a first oblique direction D1 inclined with respect to each of a first horizontal direction X and a second horizontal direction Y. A plurality of word lines WL may extend in parallel to each other along the first horizontal direction X across the plurality of active areas AC. A plurality of bit lines BL may extend in parallel to each other along the second horizontal direction Y over the plurality of word lines WL. The plurality of bit lines BL may be connected to the plurality of active areas AC through bit line contacts DC.

A plurality of buried contacts BC may be formed between two adjacent bit lines BL among the plurality of bit lines BL. A plurality of landing pads LP may be formed on the plurality of buried contacts BC. The plurality of buried contacts BC and the plurality of landing pads LP may have a function of connecting a lower electrode 182 of a capacitor structure CAP formed on the plurality of bit lines BL, to the active areas AC. The plurality of landing pads LP may be arranged to partially overlap the buried contacts BC and the bit lines BL, respectively.

The substrate 110 may include silicon, for example, single crystal silicon, polycrystalline silicon, or amorphous silicon. In some other embodiments, the substrate 110 may include at least one selected from among Ge, SiGe, SiC, GaAs, InAs, and InP. In some embodiments, the substrate 110 may include a conductive area, for example, a well that is doped with impurities, or a structure doped with impurities.

The device isolation layer 112 may include, for example, an oxide layer, a nitride layer, or a combination thereof. A first buffer insulating layer 114 and a second buffer insulating layer 116 may be sequentially arranged on an upper surface of the substrate 110. Each of the first buffer insulating layer 114 and the second buffer insulating layer 116 may include, for example, silicon oxide, silicon oxynitride, or silicon nitride.

A plurality of word line trenches 120T extending in the first horizontal direction X may be arranged on the substrate 110, and a buried gate structure 120 may be arranged in the plurality of word line trenches 120T. The buried gate structure 120 may include a gate dielectric layer 122, a gate electrode 124, and a word line capping layer 126 arranged in each of the plurality of word line trenches 120T. The plurality of gate electrodes 124 may correspond to the plurality of word lines WL illustrated in FIG. 2.

The plurality of gate dielectric layers 122 may include, for example, a silicon oxide layer, a silicon nitride layer, a silicon oxynitride layer, an oxide/nitride/oxide (ONO) layer, or a high-k dielectric film having a higher dielectric constant than a silicon oxide layer. The plurality of gate electrodes 124 may include, for example, Ti, TiN, Ta, TaN, W, WN, TiSiN, WSiN, or a combination thereof. The plurality of word line capping layers 126 may include, for example, a silicon oxide layer, a silicon nitride layer, a silicon oxynitride layer, or a combination thereof. An undoped polysilicon layer or a doped polysilicon layer may be added between the plurality of gate electrodes 124 and the plurality of word line capping layers 126.

A plurality of bit line contact holes DCH may pass through the first buffer insulating layer 114 and the second buffer insulating layer 116 and extend into the substrate 110, and the plurality of bit line contacts DC may be formed in the plurality of bit line contact holes DCH. The plurality of bit line contacts DC may be connected to the plurality of active areas AC. The plurality of bit line contacts DC may include, for example, TiN, TiSiN, W, tungsten silicide, doped polysilicon, or a combination thereof. A bit line contact spacer DCS may cover a lower portion of the bit line contacts DC in the bit line contact holes DCH. The bit line contact spacer DCS may include, for example, silicon nitride.

The plurality of bit lines BL may extend along the second horizontal direction Y on the substrate 110 and on the plurality of bit line contacts DC. Each of the plurality of bit lines BL may be connected to the active areas AC through the bit line contacts DC. Each of the plurality of bit lines BL may include a conductive layer 132, an intermediate conductive layer 134, and a bit line conductive layer 136.

In some embodiments, the conductive layer 132 may include, for example, polysilicon, and the intermediate conductive layer 134 may include, for example, at least one of TiN, TiSiN, cobalt silicide, nickel silicide, and tungsten silicide. The bit line conductive layer 136 may include, for example, at least one of ruthenium (Ru), tungsten (W), cobalt (Co), titanium (Ti), and titanium nitride (TiN).

A plurality of bit line capping layers 138 may be arranged on the plurality of bit lines BL, respectively. Each of the bit line capping layers 138 may include a first capping layer 138A, a second capping layer 138B, and a third capping layer 138C sequentially arranged on upper surfaces of the plurality of bit lines BL. The first capping layer 138A, the second capping layer 138B, and the third capping layer 138C may include, for example, at least one of silicon nitride, silicon oxide, and silicon oxynitride. In some embodiments, fourth capping layer may be further formed on the third capping layer 138C.

Spacers 140 may be arranged on both sidewalls of each bit line BL. The spacer 140 may include a first spacer layer 142, a second spacer layer 144, a third spacer layer 146, and a spacer capping layer 148. In some embodiments, the first spacer layer 142, the third spacer layer 146, and the spacer capping layer 148 may include, for example, silicon nitride, and the second spacer layer 144 may include, for example, silicon oxide or air. A bottom surface of the second spacer layer 144 may be in contact with an upper surface of a bit line contact spacer DCS. The first spacer layer 142, the second spacer layer 144, and the third spacer layer 146 (e.g., a lower portion of the spacer 140) may be sequentially arranged on a sidewall of the bit line BL, and a spacer capping layer 148 (e.g., an upper portion of the spacer 140) may be arranged on a sidewall of the bit line capping layer 138. For example, upper surfaces of the first to third spacer layers 142, 144, and 146 may be arranged at a same vertical level as an upper surface of the first capping layer 138A, and a spacer capping layer 148 may be arranged on sidewalls of the second capping layer 138B and the third capping layer 138C. Accordingly, the spacer 140 may have a shape in which an upper width thereof is smaller than a lower width thereof. As used herein, “a surface A and a surface B are at a same vertical level” (or similar language) means that the surfaces A and B are spaced apart from the substrate 110 by an equal distance.

In some embodiments, an upper width of the spacer capping layer 148 may be greater than a lower width of the spacer capping layer 148. For example, the upper width of the spacer capping layer 148 in a region adjacent to the upper surface of the third capping layer 138C (or at the same vertical level as an upper surface of the third capping layer 138C) may be greater than the lower width of the spacer capping layer 148 in a region adjacent to the upper surface of the second capping layer 138B (or at the same vertical level as the upper surface of the second capping layer 138B).

The plurality of buried contacts BC may be arranged between two adjacent bit lines BL of the plurality of bit lines BL. For example, bottom portions BC_B of the plurality of buried contacts BC may be arranged in a buried contact hole BCH extending into the substrate 110 between two adjacent bit lines BL, and the bottom portion BC_B of the buried contacts BC may be in contact with the active areas AC. In some embodiments, the plurality of buried contacts BC may include, for example, doped polysilicon. The plurality of buried contacts BC may have upper surfaces that are arranged at the same level as the upper surfaces of the first spacer layer 142 or the second spacer layer 144. In some other embodiments, the plurality of buried contacts BC may have an upper surface arranged at the same level as an upper surface of the third spacer layer 146.

Between two adjacent bit lines BL, a plurality of insulation fences 150 may be arranged along the second horizontal direction Y. The plurality of insulation fences 150 may be arranged at positions vertically overlapping the plurality of word line trenches 120T. In a plan view, the plurality of buried contacts BC and the plurality of insulation fences 150 may be alternately arranged between two adjacent bit lines BL extending in the second horizontal direction Y. The plurality of insulation fences 150 may be arranged at positions respectively corresponding to a plurality of recesses 126R defined by an upper surface of the word line capping layer 126 within the word line trench 120T. For example, bottom portions of the plurality of insulation fences 150 may be arranged in the plurality of recesses 126R, respectively. As used herein, “an element A vertically overlapping an element B” (or similar language) means that at least one vertical line intersecting both the elements A and B exists.

As illustrated in FIG. 3, the bottom portions BC_B of the buried contacts BC observed in a cross-sectional view along the first horizontal direction X may extend into the substrate 110 (or into the active areas AC and/or into the device isolation layers 112) and have a rounded shape. For example, the bottom portions BC_B of the buried contacts BC may have a first sidewall facing the bit line contacts DC and a second sidewall opposite to the first sidewall, and second sidewalls of the buried contacts BC may have a rounded shape extending into the active areas AC. As illustrated in FIG. 5, the bottom portions BC_B of the buried contacts BC observed in a cross-sectional view along the second horizontal direction Y may extend into the substrate 110 (or into the active areas AC and/or into the device isolation layers 112) and have a flat shape. Accordingly, the buried contacts BC may have a rounded bottom portion along the first horizontal direction X and a flat, rectangular shape along the second horizontal direction Y, and one side thereof may be longer than the other.

Insulating layers 152 may be arranged between the plurality of buried contacts BC and the plurality of insulation fences 150 alternately arranged along the second horizontal direction Y. The insulating layers 152 may extend from a same vertical level as upper surfaces of the buried contacts BC to a same vertical level as bottom surfaces of the buried contacts BC. In some embodiments, the insulating layers 152 may be arranged on lower portions of sidewalls of the plurality of insulation fences 150 (as illustrated in FIG. 8, the insulating layers 152 may be arranged on sidewalls of the plurality of insulation fences 150 at the first vertical level LV1), and may not be arranged on upper portions of the sidewalls of the plurality of insulation fences 150 (as illustrated in FIG. 9, the insulation layers 152 may not be arranged on sidewalls of the plurality of insulation fences 150 at the second vertical level LV2). The insulating layers 152 may be formed between the plurality of insulation fences 150 and the buried contacts BC, but in some other embodiments, the insulating layers 152 may also be formed between the plurality of insulation fences 150 and the bit lines BL (e.g., between the plurality of insulation fences 150 and the third spacer layer 146).

In some embodiments, as illustrated in FIG. 8, the plurality of buried contacts BC may include a pair of first sidewalls BS1 spaced apart from each other in the second horizontal direction Y and a pair of second sidewalls BS2 spaced apart from each other in the first horizontal direction X, and the insulating layers 152 may be arranged on the pair of first sidewalls BS1. In some embodiments, the insulating layers 152 may include silicon oxide, for example, silicon oxide formed on sidewalls of the plurality of buried contacts BC by a selective oxidation process. In some embodiments, the insulating layers 152 may have a thickness of about 2 angstroms to about 20 angstroms.

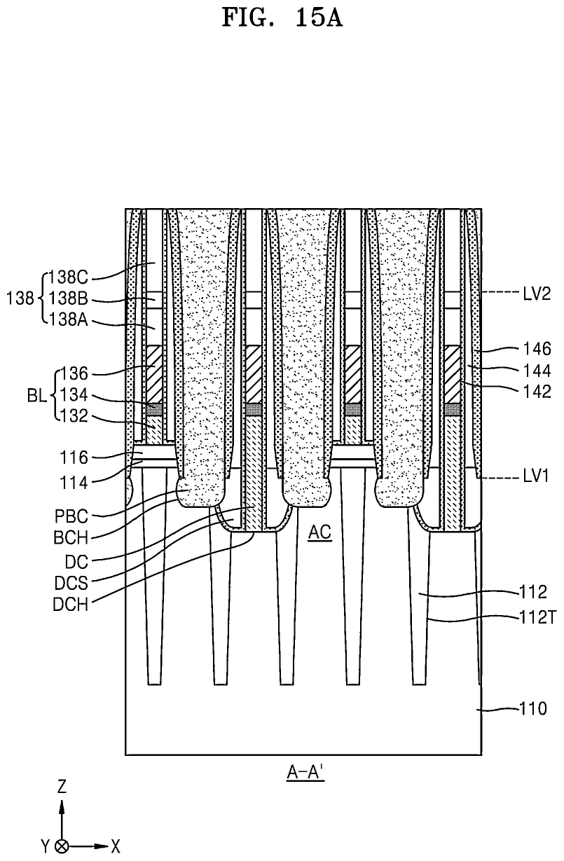

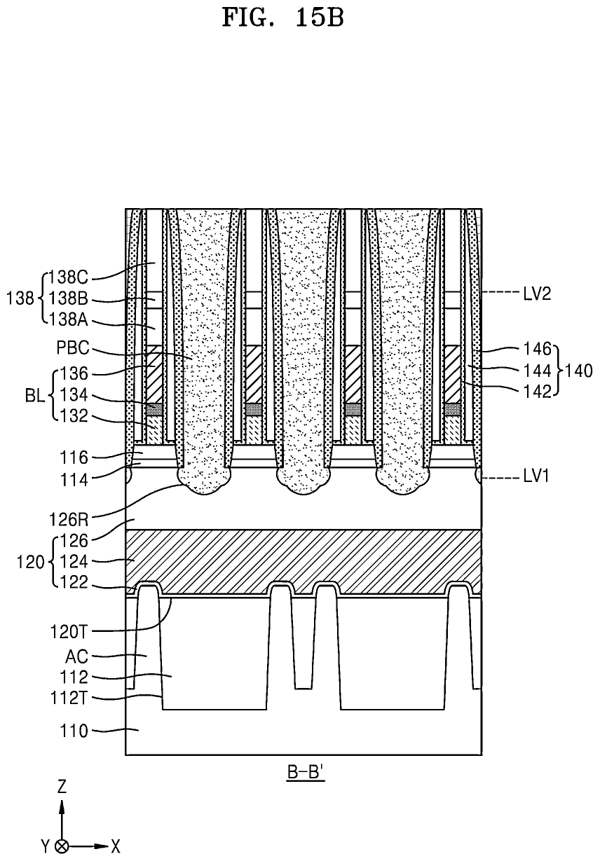

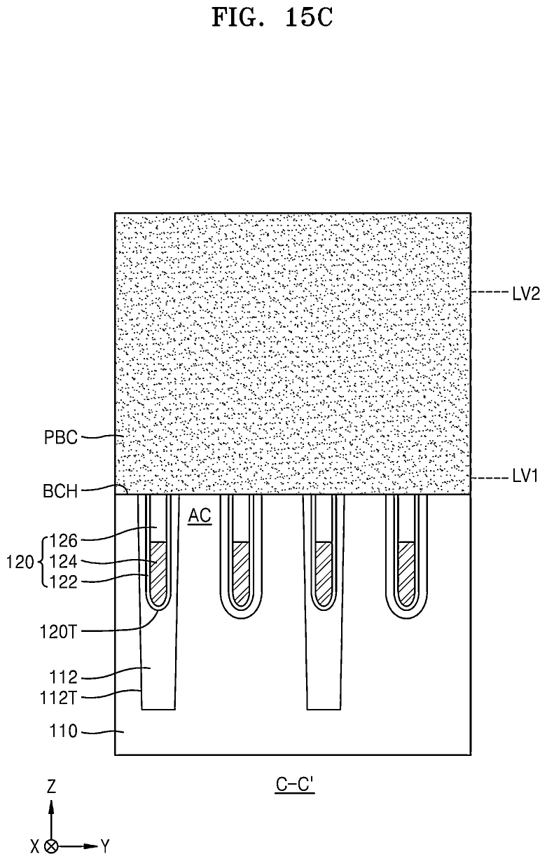

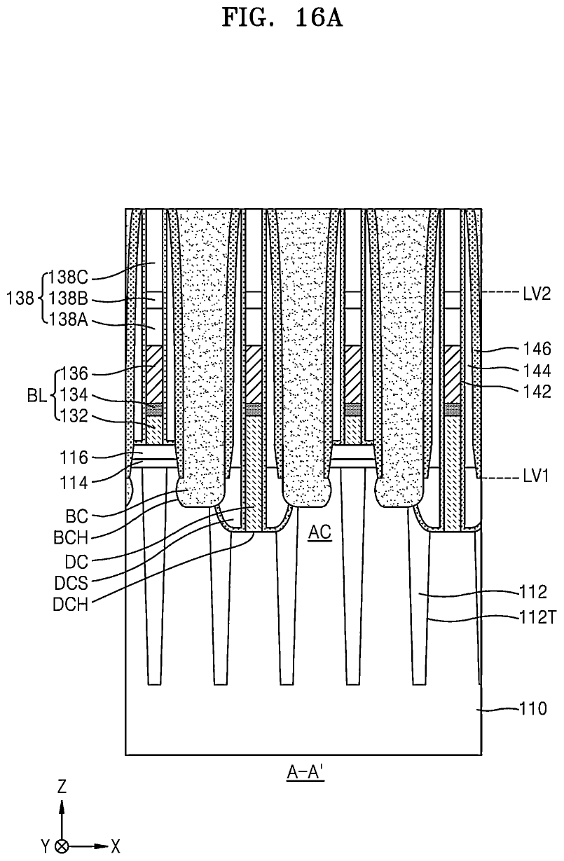

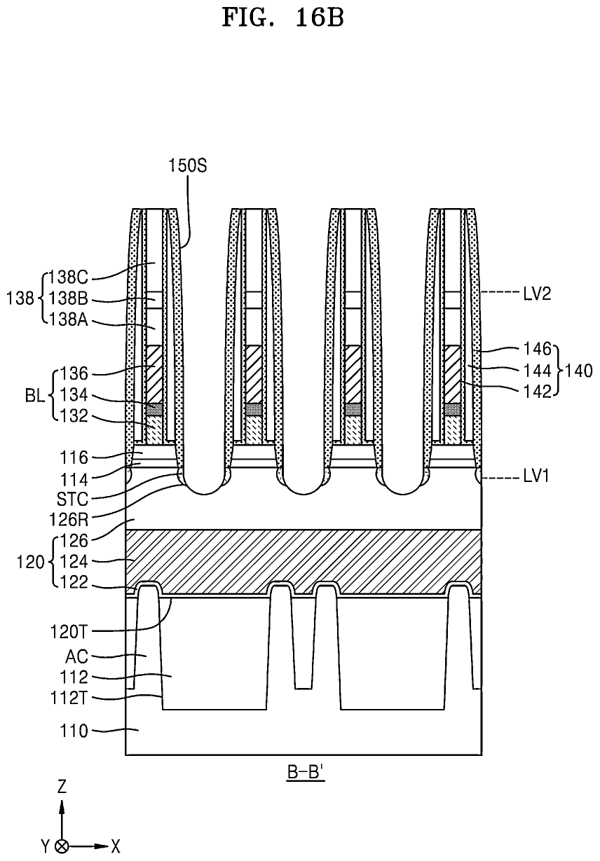

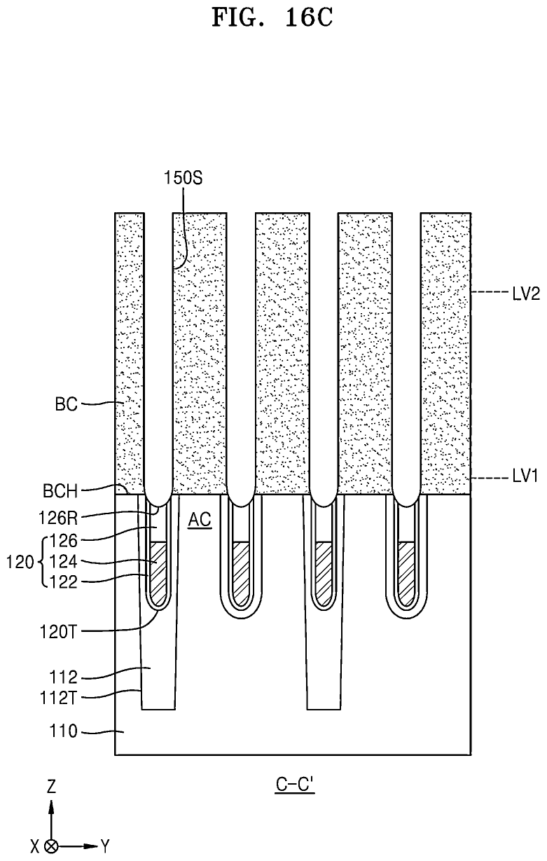

A string insulating layer 154 may be arranged on a sidewall of at least one insulation fence 150 among the plurality of insulation fences 150 in a plurality of recesses. The string insulating layer 154 may be arranged on the sidewall of the insulation fence 150 and below the spacer 140. In some embodiments, the string insulating layer 154 may include silicon oxide, and, for example, by performing an oxidation process on a portion of a string conductive layer STC (see FIG. 16B) in which a portion of a preliminary contact layer PBC (see FIG. 15A) is not removed but remains. In some embodiments, the string insulating layer 154 may have a thickness of about 2 angstroms to about 20 angstroms. The string insulating layer 154 may be connected to the insulating layer 152.

In some embodiments, in a plan view, the string insulating layer 154 may be arranged between two buried contacts BC adjacent to each other in the second horizontal direction Y, among the plurality of buried contacts BC. For example, as illustrated in FIG. 8, at the first vertical level LV1, a first end of the string insulating layer 154 may be connected to a first buried contact among the two adjacent buried contacts BC, and a second end of the string insulating layer 154 may be connected to a second buried contact among the two adjacent buried contacts BC.

A plurality of landing pads LP may be formed on the plurality of buried contacts BC. Each of the plurality of landing pads LP may include a conductive barrier layer (not shown) and a landing pad conductive layer (not shown). The conductive barrier layer may include, for example, Ti, TiN, or a combination thereof. The landing pad conductive layer may include, for example, metal, metal nitride, conductive polysilicon, or a combination thereof. For example, the landing pad conductive layer may include W. The plurality of landing pads LP may have a plurality of island-shaped pattern shapes, when viewed from a plan view. The landing pads LP may be in contact with the upper surfaces of the buried contacts BC and the upper surface of the insulating layers 152. Also, the landing pads LP may be in contact with the upper portions of the sidewalls of the insulation fences 150.

As illustrated in FIG. 9 as an example, the plurality of landing pads LP at the second vertical level LV2 may be in contact with the sidewalls of the plurality of insulation fences 150, and the plurality of landing pads LP may not have the insulating layer 152 arranged between the plurality of insulation fences 150. The plurality of landing pads LP may be arranged between the plurality of insulation fences 150 and between the plurality of bit lines BL, and as an upper portion of the spacer 140 contacting the plurality of landing pads LP has a relatively small width, the plurality of landing pads LP may have a relatively large width. For example, as illustrated in FIG. 3, a lower width W1 of the landing pads LP may be greater than an upper width W2 of the landing pads LP.

The plurality of landing pads LP may be electrically insulated from each other by an insulating pattern 168 surrounding the plurality of landing pads LP. The insulating pattern 168 may include, example, at least one of silicon nitride, silicon oxide, and silicon oxynitride.

A capacitor structure CAP may be arranged on the plurality of landing pads LP. The capacitor structure CAP may include the lower electrode 182, a capacitor dielectric layer 184, and an upper electrode 186.

In general, a plurality of insulation fences 150 are first formed in a space between the plurality of bit lines BL, and the plurality of buried contact holes BCH are formed by using the plurality of bit lines BL and the insulation fence 150 as an etching mask. However, as the width of the buried contact hole BCH is relatively small and the aspect ratio is increased, there is a problem in that defects occur in an etching process.

However, according to some embodiments of the inventive concept, the buried contact holes BCH which are a line type or trench type are formed by removing a portion of the substrate 110 exposed to the space between the plurality of bit lines BL, and a preliminary contact layer filling the space between the plurality of bit lines BL may be formed and patterned to form the plurality of buried contacts BC. Then, the insulating layers 152 may be formed by performing a selective oxidation process on exposed sides of the plurality of buried contacts BC, and the insulation fences 150 filling the space between the plurality of buried contacts BC may be formed. Accordingly, polysilicon residues (or string conductive layers) remaining in a process of removing the preliminary contact layer may be oxidized in the selective oxidation process, and accordingly, generation of defective bridges between the buried contacts BC may be reduced or prevented. Accordingly, the semiconductor device 100 may have excellent electrical characteristics.

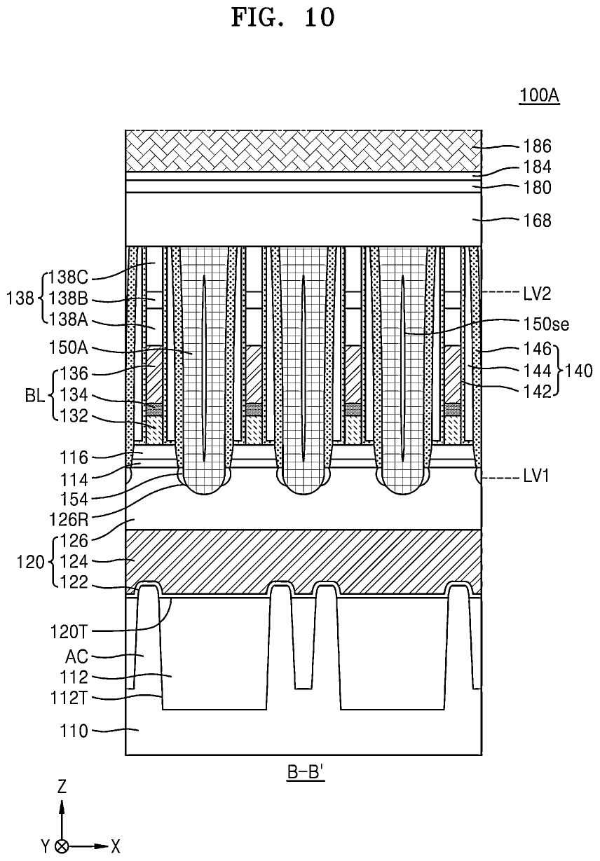

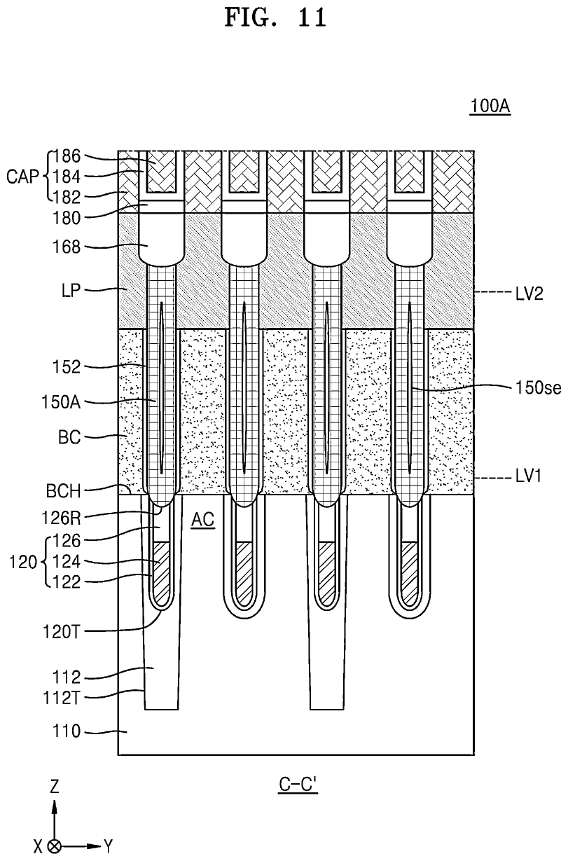

FIGS. 10 and 11 are each a cross-sectional view of a semiconductor device 100A according to some embodiments.

Referring to FIGS. 10 and 11, a plurality of insulation fences 150A may each include therein a seam 150se. The seam 150se may be an air space or air gap extending in a vertical direction Z inside the plurality of insulation fences 150. For example, the seam 150se may refer to an empty space formed inside the plurality of insulation fences 150A as upper portions of the plurality of insulation fences 150A are covered while the insides of the plurality of insulation fences 150A are not completely filled in a process of forming the plurality of insulation fences 150A. As used herein, “air gap” may be, for example, any void or cavity, and may be a gap filled with air (e.g., an air-gap), a gap filled with an inert gas or gases (e.g., an inert gas gap), a gap defining a vacuum (e.g., a vacuum gap), etc.

In some embodiments, the plurality of insulation fences 150A may be formed by filling an insulation material in a space between two buried contacts BC arranged apart from each other in the second horizontal direction Y in the space between two bit lines BL spaced apart from each other in a first horizontal direction X. Therefore, the seam 150se may have the same or similar width in the first horizontal direction X and the second horizontal direction Y, and may extend in a longitudinal direction parallel to the vertical direction Z.

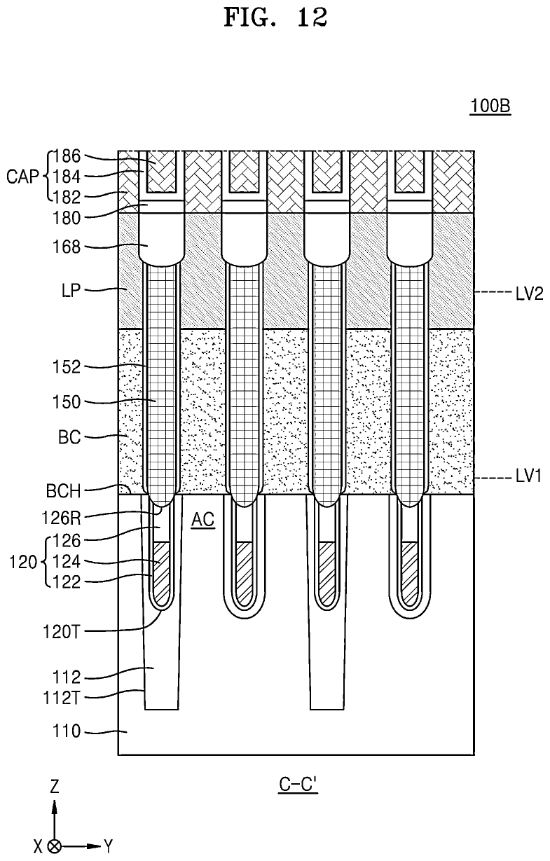

FIG. 12 is a cross-sectional view of a semiconductor device 100B according to some embodiments.

Referring to FIG. 12, the insulating layers 152 may be between the sidewalls of the plurality of insulation fences 150 and the sidewalls of the buried contacts BC adjacent to the sidewalls, and extend between the sidewalls of the plurality of insulation fences 150 and the sidewalls of the landing pads LP. The insulating layers 152 may be arranged on all of the two sidewalls spaced apart in the second horizontal direction Y of the plurality of insulation fences 150, and have an upper surface arranged at the same level as the upper surfaces of the plurality of insulation fences 150.

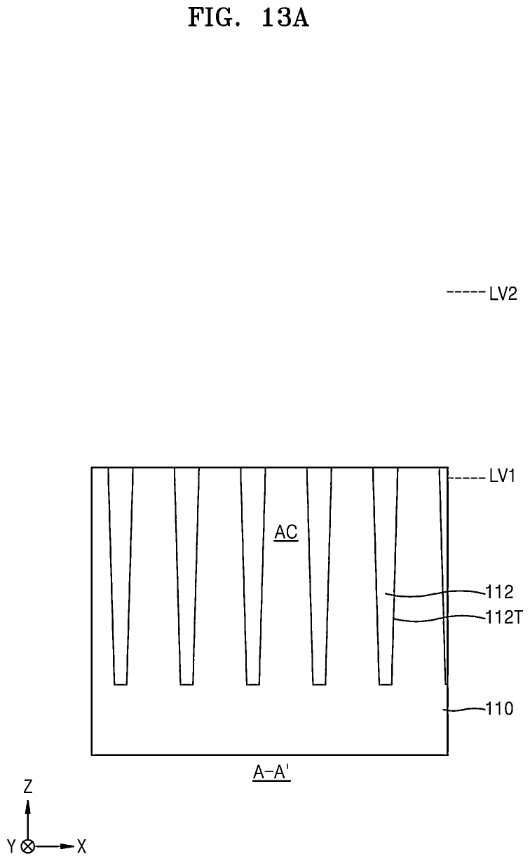

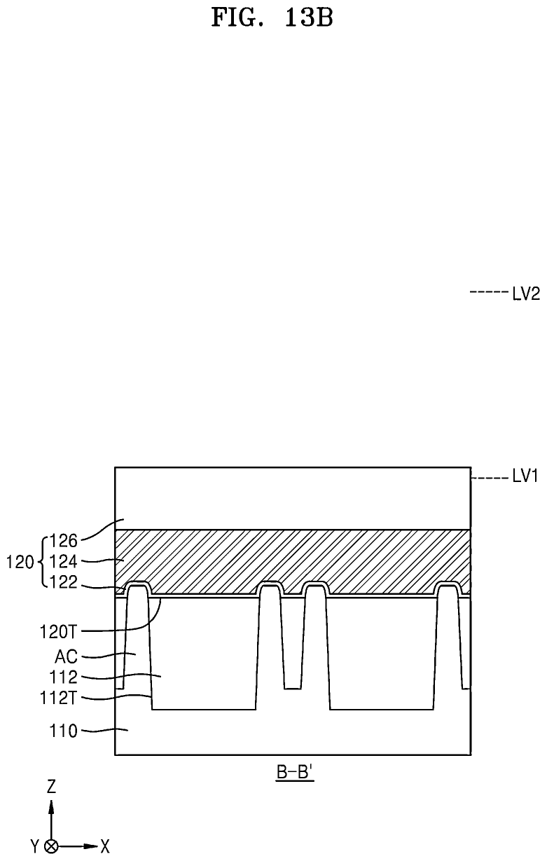

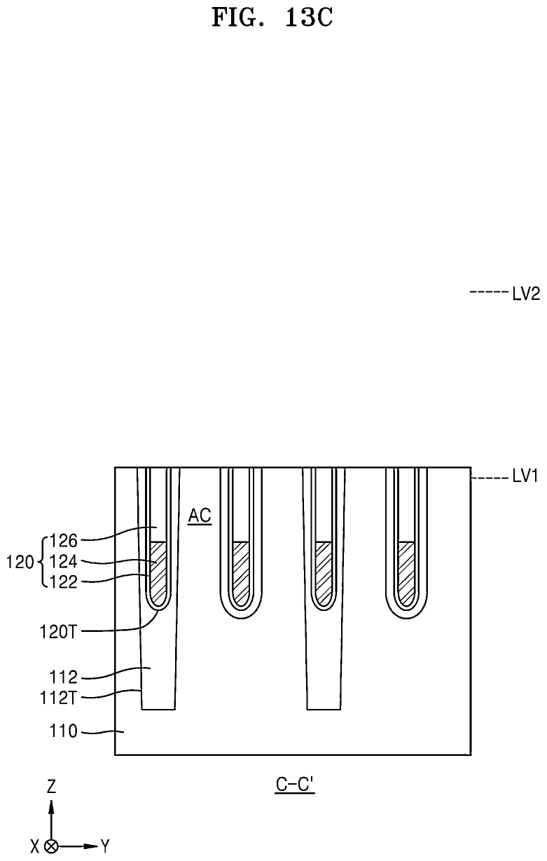

FIGS. 13A to 20C are cross-sectional view illustrating a manufacturing method of the semiconductor device 100, according to some embodiments. In detail, FIGS. 13A, 14A, 15A, 16A, 17A, 18A, 19A, and 20A are cross-sectional views corresponding to cross-section A-A′ of FIG. 2. FIGS. 13B, 14B, 15B, 16B, 17B, 18B, 19B, and 20B are cross-sectional views corresponding to cross-section B-B′ of FIG. 2. FIGS. 13C, 14C, 15C, 16C, 17C, 18C, 19C, and 20C are cross-sectional views corresponding to cross-section C-C′ of FIG. 2.

Referring to FIGS. 13A to 13C, the plurality of device isolation trenches 112T may be formed in the cell array area MCA of the substrate 110.

Then, the device isolation layer 112 filling the plurality of device isolation trenches 112T may be formed. The plurality of first active areas AC may be defined in the substrate 110 by the device isolation layer 112. The plurality of first active areas AC may extend along the first oblique direction D1 inclined at a certain angle with respect to each of the first horizontal direction X and the second horizontal direction Y.

In some embodiments, the device isolation layer 112 may be formed using silicon oxide, silicon nitride, silicon oxynitride, or a combination thereof. In some embodiments, the device isolation layer 112 may have a double-layer structure of a silicon oxide layer and a silicon nitride layer, but is not limited thereto.

A mask pattern (not shown) may be formed on the substrate 110, and a portion of the substrate 110 may be removed using the mask pattern as an etching mask to form the word line trenches 120T. For example, a mask pattern for forming the word line trenches 120T may be formed using a double patterning technique (DPT) or a quadruple patterning technique (QPT), but is not limited thereto.

Then, the gate dielectric layer 122, the gate electrode 124, and the word line capping layer 126 may be sequentially formed in the word line trench 120T.

For example, the gate dielectric layer 122 may be conformally arranged on an inner wall of the word line trench 120T. The gate electrode 124 may be formed by filling the word line trench 120T with a conductive layer (not shown) and then exposing a portion of an upper portion of the word line trench 120T again by etching back an upper portion of the conductive layer.

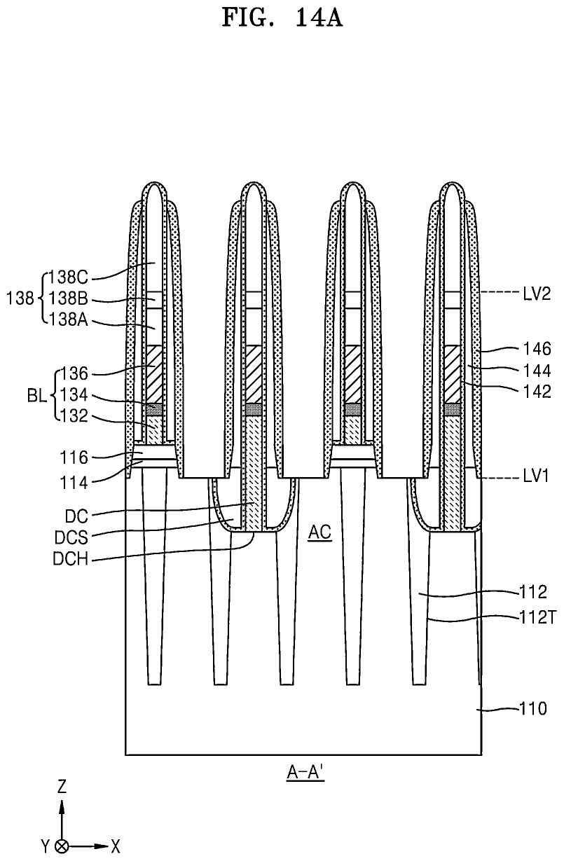

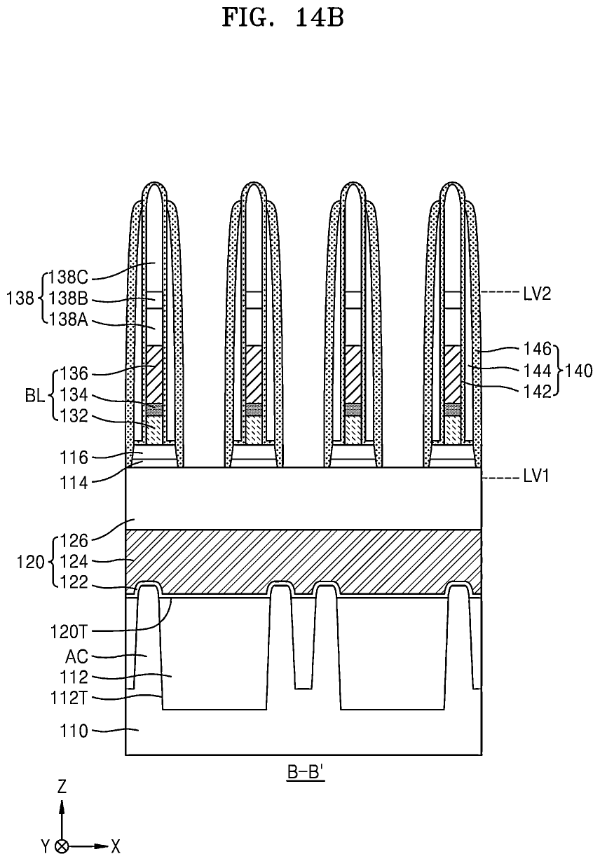

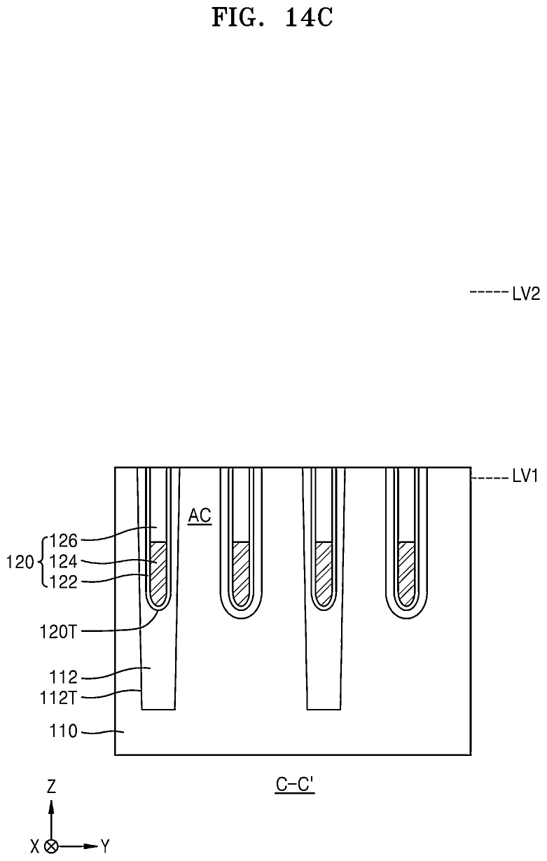

Referring to FIGS. 14A to 14C, the first buffer insulating layer 114 and the second buffer insulating layer 116 may be formed on the active area AC and the device isolation layer 112. Then, the conductive layer 132 may be formed on the first and second buffer insulating layers 114 and 116, and a bit line contact hole DCH may be formed by removing a portion of each of the conductive layer 132, the first and second buffer insulating layers 114 and 116, and the substrate 110. Then, the bit line contact DC may be formed inside the bit line contact hole DCH.

The intermediate conductive layer 134 and the bit line conductive layer 136 may be formed on the bit line contact DC and the conductive layer 132, and the bit line capping layer 138 may be formed on the bit line conductive layer 136. Then, the bit line conductive layer 136, the intermediate conductive layer 134, and the conductive layer 132 may be patterned using the bit line capping layer 138 as an etch mask to form the plurality of bit lines BL.

In some embodiments, the intermediate conductive layer 134 may include at least one of TiN, TiSiN, cobalt silicide, nickel silicide, and tungsten silicide. The bit line conductive layer 136 may include, for example, at least one of ruthenium (Ru), tungsten (W), cobalt (Co), titanium (Ti), and titanium nitride (TiN).

Thereafter, the first spacer layer 142, the second spacer layer 144, and the third spacer layer 146 may be sequentially formed on the sidewalls of the bit line BL and the bit line capping layer 138. In some embodiments, the first spacer layer 142 and the third spacer layer 146 may include silicon nitride, and the second spacer layer 144 may include silicon oxide.

In some embodiments, after forming the first spacer layer 142 on the sidewalls of the bit line BL and the bit line capping layer 138, an anisotropic etching process or a trimming process may be performed on the first spacer layer 142 such that the upper surface of the first spacer layer 142 and an upper surface of the bit line capping layer 138 each have a rounded shape. Next, the second spacer layer 144 may be formed on the sidewall of the first spacer layer 142, and an anisotropic etching process or a trimming process may be performed on the second spacer layer 144. Next, the third spacer layer 146 may be formed on the sidewall of the second spacer layer 144, and an anisotropic etching process or a trimming process may be performed on the third spacer layer 146. As a result of the anisotropic etching process or the trimming process, upper widths of the second spacer layer 144 and the third spacer layer 146 are smaller than lower widths of the second spacer layer 144 and the third spacer layer 146, respectively, and the second spacer layer 144 and the third spacer layer 146 may each have a rounded upper surface, but the inventive concept is not limited thereto.

In some embodiments, in a process of forming the spacer 140, an insulation material may be filled in the bit line contact hole DCH to form the bit line contact spacer DCS. The bit line contact spacer DCS may include, for example, silicon oxide filling the inside of the bit line contact hole DCH. The bit line contact spacer DCS may further include a portion of the first spacer layer 142 extending into the bit line contact hole DCH.

Referring to FIGS. 15A to 15C, the buried contact hole BCH may be formed by further removing an upper portion of the substrate 110 exposed in the space between the plurality of bit lines BL. In some embodiments, the process of forming the buried contact hole BCH may include a wet etching process, a dry etching process, or a combination thereof. In the process of forming the buried contact hole BCH, a portion of the word line capping layer 126 exposed to the space between the plurality of bit lines BL may be removed together, and accordingly, a plurality of recesses 126R may be formed in the upper surface of the word line capping layer 126. In some embodiments, the plurality of recesses 126R may extend laterally with respect to a sidewall of the third spacer layer 146, for example, to an area below at least a portion of the third spacer layer 146.

Then, the preliminary contact layer PBC filling the inside of the buried contact hole BCH may be formed. The preliminary contact layer PBC may be formed to extend along the second horizontal direction Y. For example, a bottom surface of the preliminary contact layer PBC may be arranged on a flat level along the second horizontal direction Y. In some embodiments, a bottom portion of the preliminary contact layer PBC may fill an inside of the recesses 126R formed in the word line capping layer 126.

Referring to FIGS. 16A to 16C, the plurality of buried contacts BC may be formed by removing a portion of the preliminary contact layer PBC. The plurality of buried contacts BC may be spaced apart from each other in the first horizontal direction X and the second horizontal direction Y, and may be arranged to be connected to an upper surface of the active area AC.

In some embodiments, portions of the preliminary contact layer PBC to be removed to form the plurality of buried contacts BC may be arranged at positions corresponding to the plurality of recesses 126R. Accordingly, after the plurality of buried contacts BC are formed, the upper surface of the word line capping layer 126 may be exposed again on a bottom portion of the space between the plurality of buried contacts BC.

In an etching process for forming the plurality of buried contacts BC, a portion of the preliminary contact layer PBC or a residue of the preliminary contact layer PBC may not be removed but remain in the plurality of recesses 126R, and this portion or residue may be referred to as the string conductive layer STC. In some embodiments, the string conductive layer STC may be arranged below the third spacer layer 146 and within the plurality of recesses 126R, and connected to two buried contacts BC adjacent to each other in the second horizontal direction Y. For example, a first end of the string conductive layer STC may be connected to the first buried contact among the two adjacent buried contacts BC, and a second end of the string conductive layer STC may be connected to the second buried contact among the two adjacent buried contacts BC.

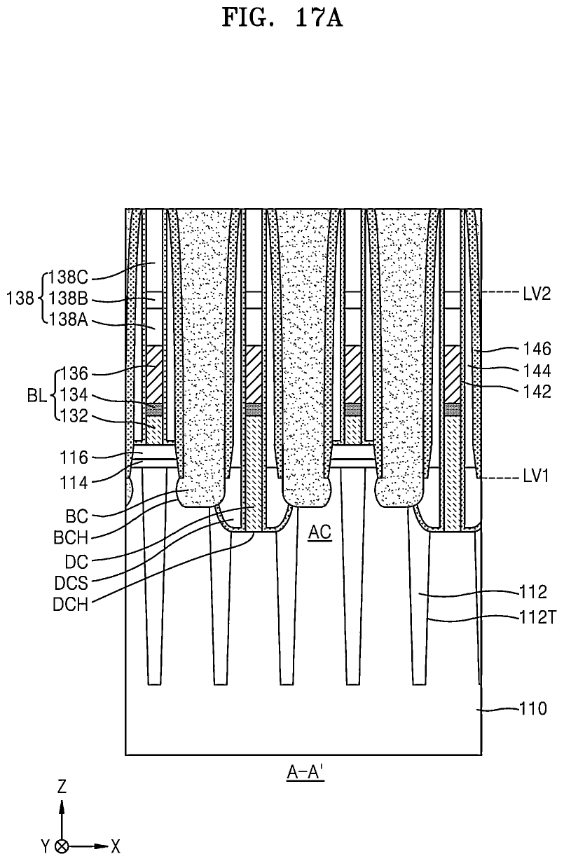

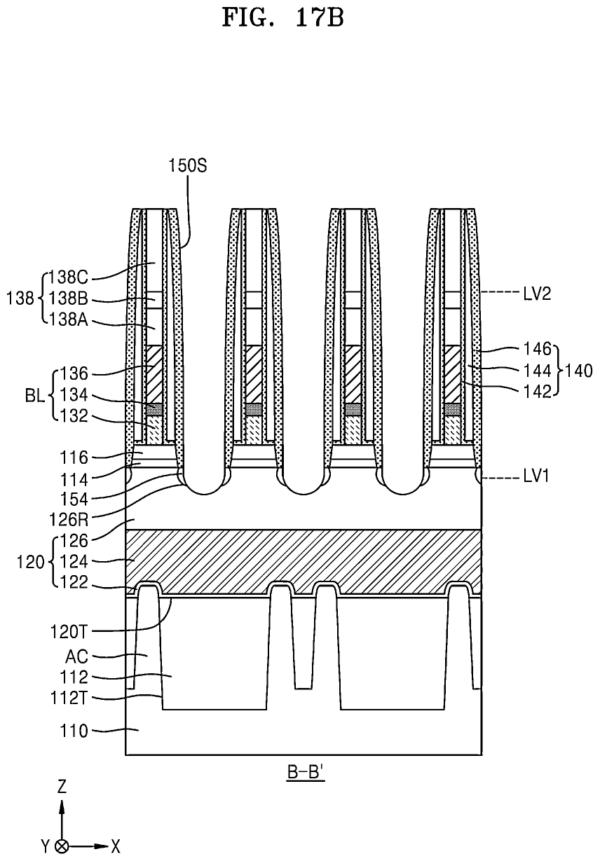

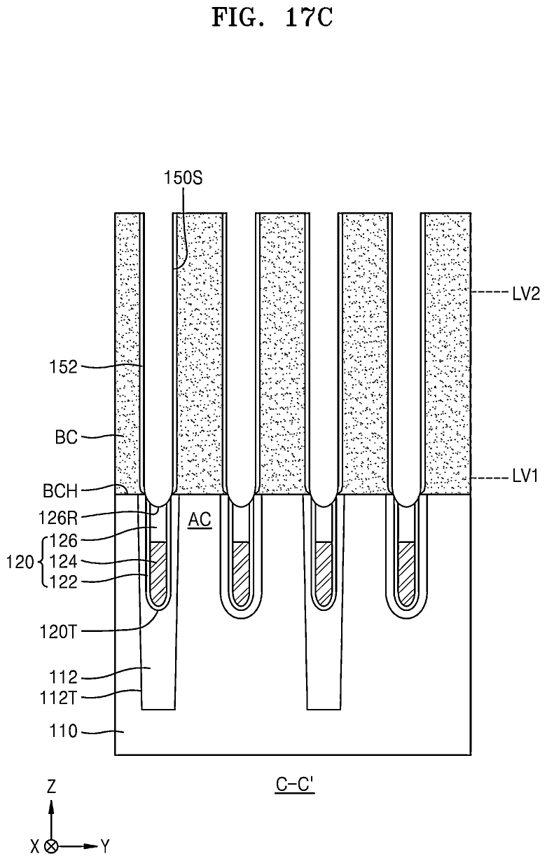

Referring to FIGS. 17A to 17C, a selective oxidation process may be performed on exposed sidewalls of the plurality of buried contacts BC. The insulating layers 152 may be formed on the exposed sidewalls of the plurality of buried contacts BC by the selective oxidation process, and the string conductive layer STC may be converted into the string insulating layer 154 by the selective oxidation process.

In some embodiments, the insulating layers 152 may be formed by converting silicon atoms in a portion of the sidewalls of the plurality of buried contacts BC into silicon oxide through an oxidation process. The insulating layers 152 may be formed on the exposed surface of the entire first sidewalls BS1 (see FIG. 8) of the plurality of buried contacts BC, which are spaced apart from each other in the second horizontal direction Y. The second sidewalls BS2 of the plurality of buried contacts BC, which are spaced apart from each other in the first horizontal direction X, may be in contact with the third spacer layer 146 and not be exposed to an oxidizing atmosphere, and no insulating layer 152 is formed on the second sidewalls BS2.

In some embodiments, the string insulating layer 154 may be formed by converting silicon atoms in the string conductive layer STC into silicon oxide by an oxidation process. Accordingly, the string insulating layer 154 may be arranged below the third spacer layer 146 and within the plurality of recesses 126R, and may be connected to two buried contacts BC adjacent to each other in the second horizontal direction Y. For example, a first end of the string insulating layer 154 may be connected to the first buried contact among the two adjacent buried contacts BC, and a second end of the string insulating layer 154 may be connected to the second buried contact among the two adjacent buried contacts BC.

As the string conductive layer STC is converted into the string insulating layer 154, an unwanted short circuit or bridging between two adjacent buried contacts BC may be reduced or prevented.

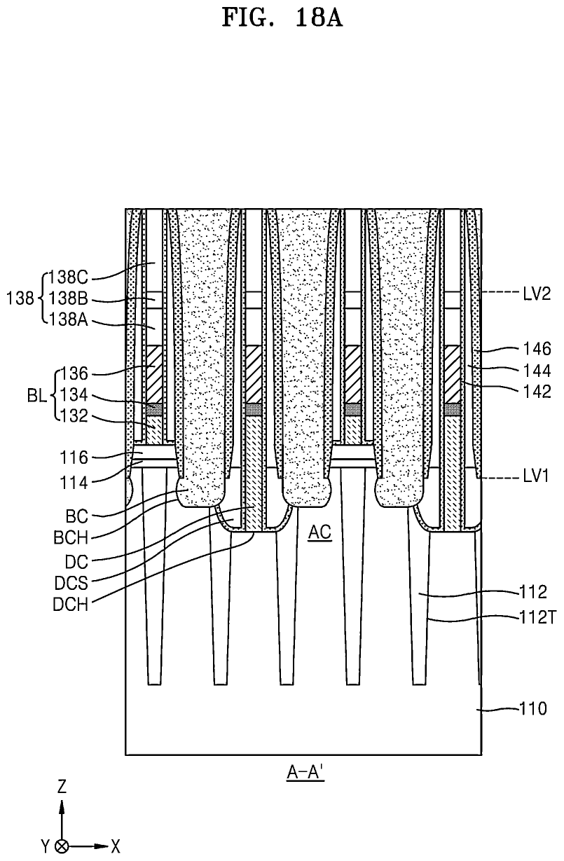

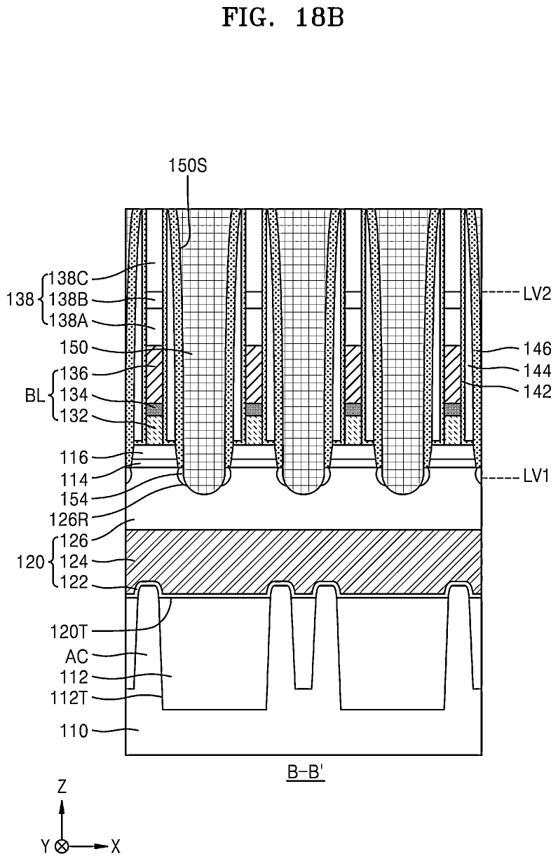

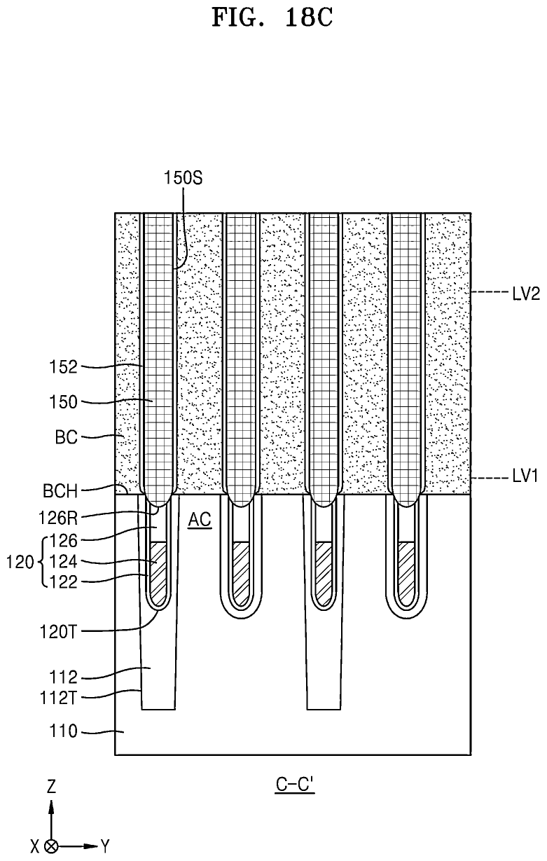

Referring to FIGS. 18A to 18C, the plurality of insulation fences 150 are formed in a space between the plurality of bit lines BL and between the plurality of buried contacts BC (e.g., an insulation fence space 150S).

In some embodiments, the plurality of insulation fences 150 may include silicon nitride. The plurality of insulation fences 150 may have upper surfaces arranged at a same level as the upper surfaces of the plurality of buried contacts BC.

In some embodiments, in a process of forming the plurality of insulation fences 150, an upper portion of the insulation fence space 150S may be covered while the inside of the insulation fence space 150S is not completely filled, and the seam 150se including an air space or air gap may be formed inside each of the plurality of insulation fences 150. In this case, the semiconductor device 100A described with reference to FIGS. 10 to 11 may be formed.

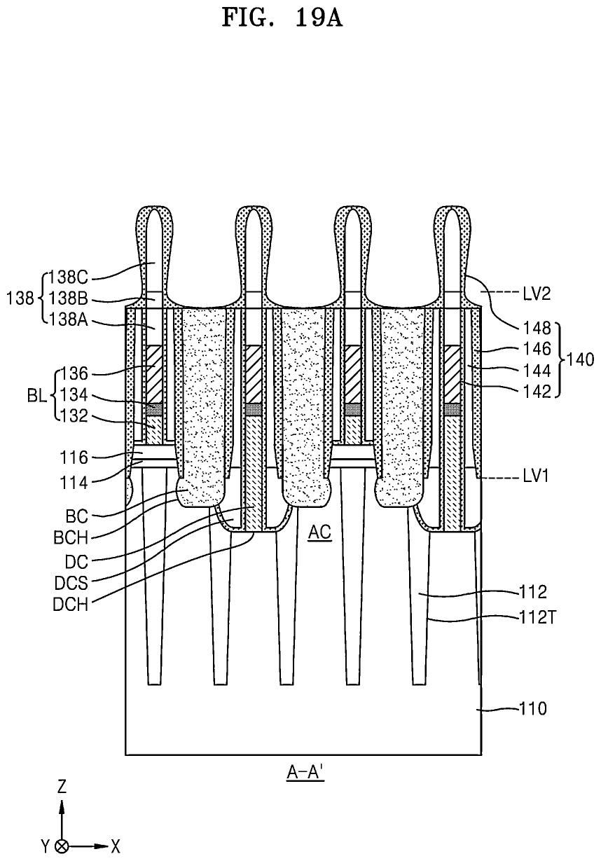

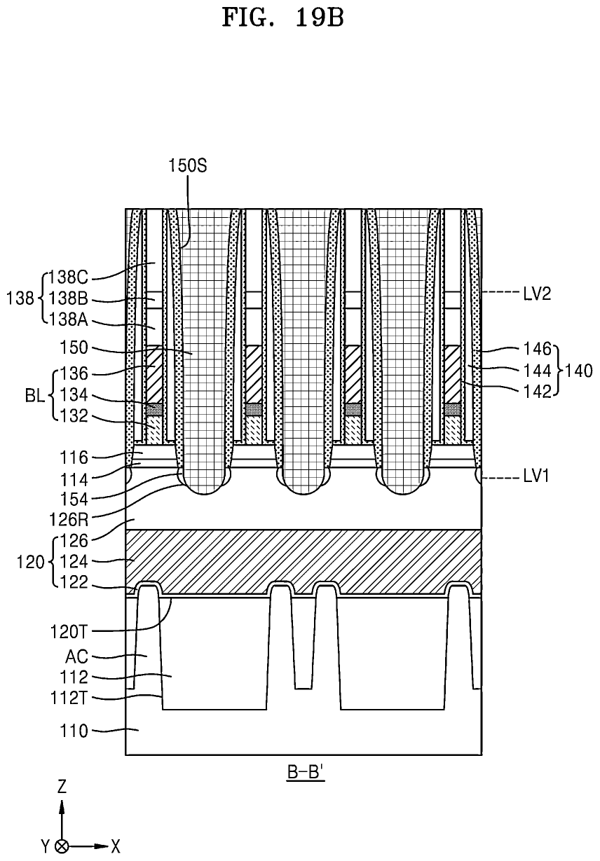

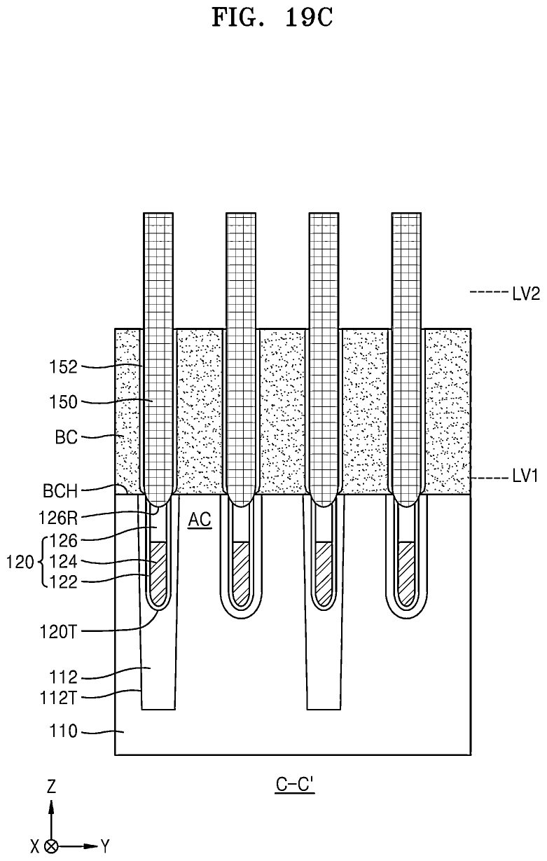

Referring to FIGS. 19A to 19C, an etch-back process may be performed on an upper portion of the plurality of buried contacts BC, thereby reducing heights of the plurality of buried contacts BC. The plurality of buried contacts BC may have upper surfaces arranged at a lower level than upper surfaces of the plurality of insulation fences 150. As used herein, “a surface A is at a lower level than a surface B” (or similar language) means that the surface A is closer than the surface B to the substrate 110.

Next, an etching process or an etch-back process may be performed on the first spacer layer 142, the second spacer layer 144, and the third spacer layer 146 arranged on the sidewall of the bit line capping layer 138 to expose the sidewall of the bit line capping layer 138. The upper surfaces of the first spacer layer 142, the second spacer layer 144, and the third spacer layer 146 may be at a same level as the upper surfaces of the plurality of buried contacts BC.

In some embodiments, the etching process or the etch-back process may be sequentially performed. For example, an upper portion of the third spacer layer 146 may be removed first, then an upper portion of the second spacer layer 144 may be removed, and then an upper portion of the first spacer layer 142 may be removed. In some embodiments, in an etching process or an etch-back process for removing the upper portion of the second spacer layer 144, a portion of the insulating layer 152 arranged on the sidewalls of the plurality of insulation fences 150 may also be removed. Accordingly, the insulating layer 152 may have an upper surface arranged at the same level as the upper surface of the plurality of buried contacts BC.

Next, the spacer capping layer 148 may be formed to cover the upper surfaces of the first to third spacer layers 142, 144, and 146. For example, the spacer capping layer 148 may be formed using silicon nitride.

The first to third spacer layers 142, 144, and 146 and the spacer capping layer 148 may be collectively referred to as the spacer 140. The spacer 140 may have a shape in which an upper width thereof is smaller than a lower width thereof.

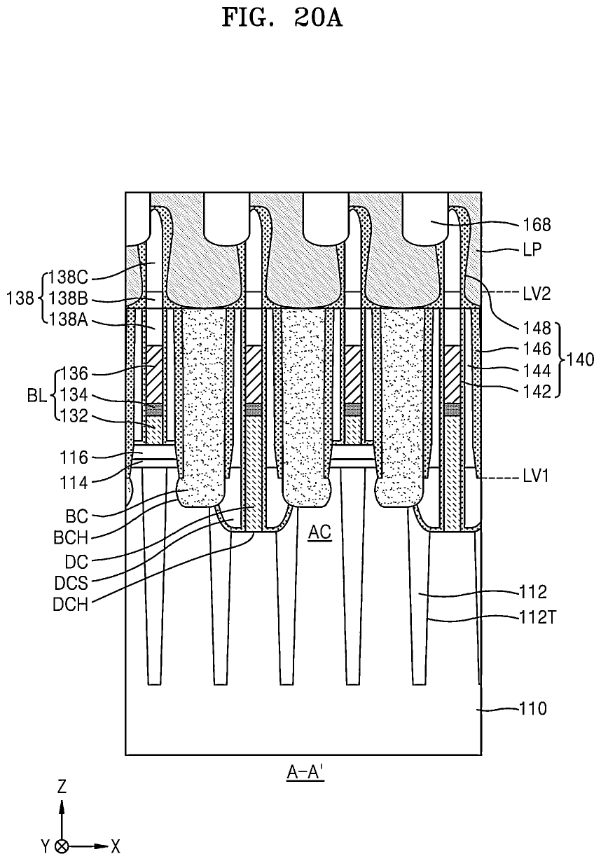

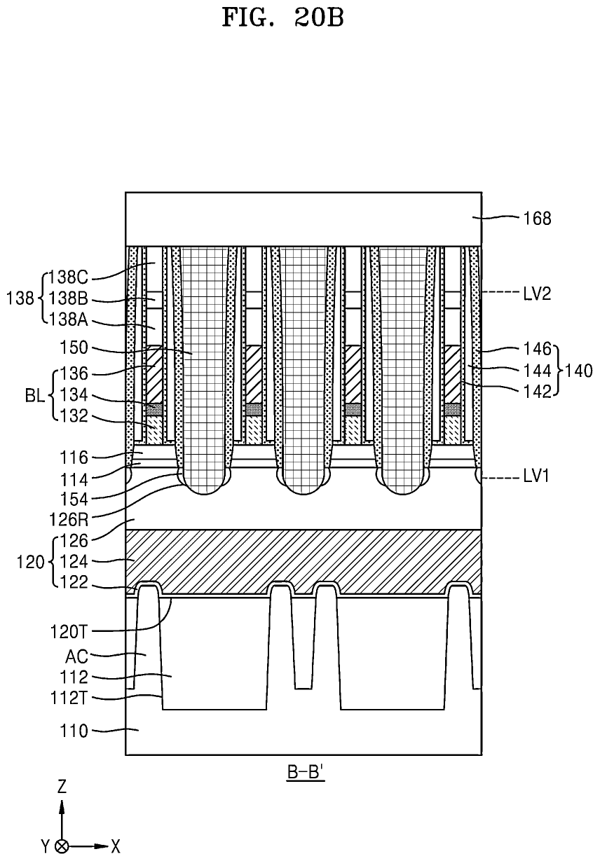

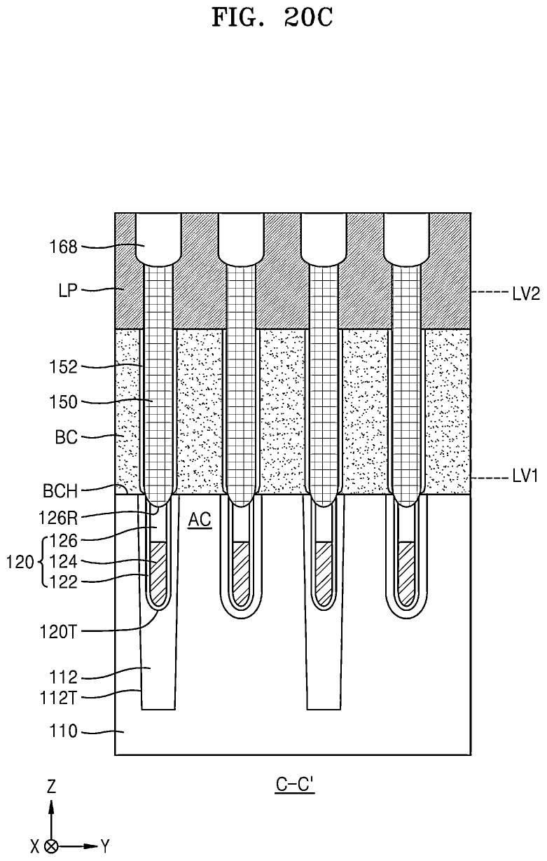

Referring to FIGS. 20A to 20C, a conductive layer (not shown) may be formed on the upper surfaces of the plurality of buried contacts BC, and the plurality of landing pads LP may be formed by removing portions of the conductive layer. Bottom portions of the plurality of landing pads LP may be arranged between the plurality of insulation fences 150 and between the plurality of bit lines BL.

The bottom portions of the plurality of landing pads LP may have a relatively large width as the spacer 140 has a shape in which the upper width thereof is smaller than the lower width thereof, and the insulating layer 152 arranged on upper sidewalls of the insulation fence 150 is removed. Accordingly, a defect in which a metal material constituting the plurality of landing pads LP is not filled in a landing pad space may be reduced or prevented, and also, a sufficiently large area between the plurality of landing pads LP and the plurality of buried contacts BC may be secured.

Then, the insulating pattern 168 covering the plurality of landing pads LP may be formed.

Referring back to FIG. 3, a plurality of lower electrodes 182 connected to the landing pads LP may be formed, and the capacitor dielectric layer 184 and the upper electrode 186 may be sequentially formed on sidewalls of the plurality of lower electrodes 182.

The semiconductor device 100 may be completed by performing the method described above.

According to embodiments of the inventive concept, the buried contact holes BCH which are a line type or trench type may be formed by removing a portion of the substrate 110 exposed to the space between the plurality of bit lines BL, and the preliminary contact layer PBC filling the space between the plurality of bit lines BL may be formed and patterned to form the plurality of buried contacts BC. Next, the insulating layer 152 may be formed by performing a selective oxidation process on the exposed side surfaces of the plurality of buried contacts BC, and the insulation fence 150 filling the space between the plurality of buried contacts BC may be formed. Accordingly, polysilicon residues (or string conductive layers) remaining after removing the preliminary contact layer PBC may be oxidized in the selective oxidation process, thereby reducing/preventing defective bridges between the buried contacts BC. Thus, the semiconductor device 100 may have excellent electrical characteristics.

Although terms (e.g., first, second or third) may be used herein to describe various elements, these elements should not be limited by these terms. These terms are only used to distinguish one element from another. For example, a first element may be referred to as a second element, and, similarly a second element may be referred to as a first element without departing from the teachings of the disclosure.

It is noted that aspects of the invention described with respect to one embodiment, may be incorporated in a different embodiment although not specifically described relative thereto. That is, all embodiments and/or features of any embodiment can be combined in any way and/or combination. These and other objects and/or aspects of the present invention are explained in detail in the specification set forth below.

While the inventive concept has been particularly shown and described with reference to some example embodiments thereof, it will be understood that various changes in form and details may be made therein without departing from the scope of the following claims. Accordingly, the above-disclosed subject matter is to be considered illustrative, and not restrictive, and the appended claims are intended to cover all such modifications, enhancements, and other embodiments, which fall within the scope of the inventive concept.

1. A semiconductor device comprising:
a substrate including a plurality of active areas defined by a device isolation layer;
a plurality of bit lines extending on the substrate in a first horizontal direction;
a plurality of insulation fences that are spaced apart from each other in the first horizontal direction and are between two adjacent bit lines among the plurality of bit lines on the substrate;
a plurality of buried contacts that are between the two adjacent bit lines among the plurality of bit lines and are arranged alternately with the plurality of insulation fences along the first horizontal direction on the substrate, the plurality of buried contacts being connected to the plurality of active areas, respectively; and
a plurality of insulating layers, each of which is between a respective one of the plurality of insulation fences and a respective one of the plurality of buried contacts.

2. The semiconductor device of claim 1, wherein each of the plurality of buried contacts comprises a pair of first sidewalls spaced apart from each other in the first horizontal direction and a pair of second sidewalls spaced apart from each other in a second horizontal direction that crosses the first horizontal direction, and
each of the plurality of insulating layers is on a respective one of the pair of first sidewalls of the plurality of buried contacts.

3. The semiconductor device of claim 2, wherein the plurality of insulating layers are not on the pair of second sidewalls of the plurality of buried contacts.

4. The semiconductor device of claim 1, wherein the plurality of insulation fences each have an upper surface at a higher level than upper surfaces of the plurality of buried contacts, and
upper surfaces of the plurality of insulating layers are at the same level as the upper surfaces of the plurality of buried contacts.

5. The semiconductor device of claim 4, wherein each of the plurality of insulating layers is on a lower sidewall of a respective one of the plurality of insulating fences, and
the plurality of insulating layers are not on upper sidewalls of the plurality of insulation fences.

6. The semiconductor device of claim 1, wherein each of the plurality of insulating layers has a thickness of about 2 angstroms to about 20 angstroms.

7. The semiconductor device of claim 1, further comprising:
a word line in a lower portion of a word line trench extending in a second horizontal direction crossing the first horizontal direction in the substrate;
a word line capping layer in an upper portion of the word line trench and on an upper surface of the word line; and
a plurality of spacers on respective sidewalls of the plurality of bit lines.

8. The semiconductor device of claim 7, wherein an upper surface of the word line capping layer comprises a plurality of recesses, and the plurality of insulation fences are respectively on the plurality of recesses, and
the semiconductor device further comprises a string insulating layer in at least one recess among the plurality of recesses, and the string insulating layer is vertically overlapped by one of the plurality of spacers and is on a sidewall of one the plurality of insulation fences.

9. The semiconductor device of claim 8, wherein the string insulating layer is between two buried contacts that are adjacent to each other in the first horizontal direction,
a first end of the string insulating layer is connected to a first buried contact among the two buried contacts, and
a second end of the string insulating layer opposite the first end is connected to a second buried contact among the two buried contacts.

10. The semiconductor device of claim 8, wherein the plurality of insulating layers comprise silicon oxide, and
the string insulating layer comprises silicon oxide.

11. A semiconductor device comprising:
a substrate including a plurality of active areas defined by a device isolation layer;
a plurality of bit lines extending on the substrate in a first horizontal direction;
a plurality of spacers on respective sidewalls of the plurality of bit lines;
a plurality of insulation fences that are spaced apart from each other in the first horizontal direction and are between two bit lines among the plurality of bit lines on the substrate, each of the plurality of bit lines contacting a respective pair of the plurality of spacers;
a plurality of buried contacts that are between the two bit lines among the plurality of bit lines and are arranged alternately with the plurality of insulation fences along the first horizontal direction on the substrate, the plurality of buried contacts being connected to the plurality of active areas, respectively;
a plurality of insulating layers between a respective one of the plurality of insulation fences and a respective one of the plurality of buried contacts; and
a string insulating layer on a lower sidewall of at least one insulation fence among the plurality of insulation fences and under one of the plurality of spacers.

12. The semiconductor device of claim 11, wherein each of the plurality of insulation fences comprises a pair of first sidewalls spaced apart from each other in the first horizontal direction and a pair of second sidewalls spaced apart from each other in a second horizontal direction that crosses the first horizontal direction, and
each of the plurality of insulating layers is on a respective one of the pair of first sidewalls of the plurality of insulation fences.

13. The semiconductor device of claim 12, wherein each of the plurality of buried contacts comprises a pair of first sidewalls spaced apart from each other in the first horizontal direction and a pair of second sidewalls spaced apart from each other in the second horizontal direction, and
the plurality of insulating layers are not on the pair of second sidewalls of the plurality of buried contacts, and
the pair of second sidewalls of each of the plurality of buried contacts are respectively in contact with two spacers of the plurality of spacers.

14. The semiconductor device of claim 11, wherein the plurality of insulation fences each have an upper surface at a higher level than upper surfaces of the plurality of buried contacts, and
upper surfaces of the plurality of insulating layers are at the same level as the upper surfaces of the plurality of buried contacts.

15. The semiconductor device of claim 11, further comprising:
a word line in a lower portion of a word line trench extending in a second horizontal direction crossing the first horizontal direction in the substrate; and
a word line capping layer in an upper portion of the word line trench and on an upper surface of the word line,
wherein an upper surface of the word line capping layer comprises a plurality of recesses, and the plurality of insulation fences are respectively on the plurality of recesses.

16. The semiconductor device of claim 11, wherein the string insulating layer is between two buried contacts adjacent to each other in the first horizontal direction,
a first end of the string insulating layer is connected to a first buried contact among the two buried contacts, and
a second end of the string insulating layer opposite the first end is connected to a second buried contact among the two buried contacts.

17. The semiconductor device of claim 11, wherein the plurality of insulating layers comprise silicon oxide, and
the string insulating layer comprises silicon oxide.

18. A semiconductor device comprising:
a substrate including a plurality of active areas defined by a device isolation layer;
a plurality of bit lines extending on the substrate in a first horizontal direction;
a plurality of spacers on respective sidewalls of the plurality of bit lines;
a word line in a lower portion of a word line trench extending in a second horizontal direction crossing the first horizontal direction in the substrate;
a word line capping layer in an upper portion of the word line trench and on an upper surface of the word line;
a plurality of insulation fences that are spaced apart from each other in the first horizontal direction and are between two bit lines among the plurality of bit lines on the substrate, each of the plurality of bit lines contacting a respective pair of the plurality of spacers;
a plurality of buried contacts that are between the two bit lines among the plurality of bit lines and are arranged alternately with the plurality of insulation fences along the first horizontal direction on the substrate, the plurality of buried contacts being connected to the plurality of active areas, respectively;
a plurality of insulating layers, each of which is between a respective one of the plurality of insulation fences and a respective one of the plurality of buried contacts;
a string insulating layer that is on a lower sidewall of at least one insulation fence among the plurality of insulation fences and is under one of the plurality of spacers; and
a plurality of landing pads respectively on the plurality of buried contacts.

19. The semiconductor device of claim 18, wherein an upper surface of the word line capping layer comprises a plurality of recesses, and the plurality of insulation fences are respectively on the plurality of recesses, and
an upper surface of the string insulating layer is at a lower level than a bottom surface of the bit lines.

20. The semiconductor device of claim 18, wherein each of the plurality of insulation fences comprises a pair of first sidewalls spaced apart from each other in the first horizontal direction and a pair of second sidewalls spaced apart from each other in the second horizontal direction, and
each of the plurality of insulating layers is on a respective one of the pair of first sidewalls of the plurality of insulation fences, and
the string insulating layer is on at least one of the pair of second sidewalls of the plurality of insulation fences.

21-40. (canceled)
